(19) United States
(12) Patent Application Publication
(10) Pub. No.: US 2007/0001296 A1
(43) Pub. Date: Jan. 4, 2007

(54) BUMP FOR OVERHANG DEVICE

(75) Inventors: Hun Teak Lee, Singapore (SG); Jong Kook Kim, Singapore (SG); ChulSik Kim, Singapore (SG); Ki Youn Jang, Singapore (SG); Keon Teak Kang, Singapore (SG); Hyung Jun Jeon, Singapore (SG)

Correspondence Address: THE LAW OFFICES OF MIKIO ISHIMARU, 333 W. EL CAMINO REAL, SUITE 330, SUNNYVALE, CA, 94087, US

(73) Assignee: STATS CHIPPAC LTD., Singapore (SG)

(21) Appl. No.: 11/469,307

(22) Filed: Aug. 31, 2006

Related U.S. Application Data
(63) Continuation-in-part of application No. 11/420,853, filed on May 30, 2006.
(60) Provisional application No. 60/596,103, filed on Aug. 31, 2005.
(60) Provisional application No. 60/686,116, filed on May 31, 2005.

(51) Int. Cl. H01L 23/34

(52) U.S. Cl. 257/723

(57) ABSTRACT

A semiconductor package system is provided including forming a support platform, mounting a first device over the support platform, forming a bump on the support platform, and mounting a second device on the first device and the bump.

### CROSS-REFERENCE TO RELATED APPLICATION

This application is a continuation-in-part of co-pending U.S. patent application Ser. No. 11/420,853 filed May 30, 2006, by Hun Teak Lee, Jong Kook Kim, ChulSik Kim, and Ki Youn Jang, which is a Non Provisional of U.S. Provisional patent application Ser. No. 60/686,116 filed May 31, 2005.

This application also claims the benefit of U.S. Provisional patent application Ser. No. 60/596,103 filed Aug. 31, 2005, by Ki Youn Jang, Keon Teak Kang, and Hyung Jun Jeon.

### TECHNICAL FIELD

The present invention relates generally to semiconductor packages and more particularly to molded semiconductor packages.

### BACKGROUND ART

A conventional chip package consists of a semiconductor die affixed to a surface of a substrate and electrically interconnected to bonding pads on the substrate surface. The opposite surface of the substrate has an array of solder balls for electrical connection to, for example, a motherboard. The substrate includes, among other things, routing circuitry for mediating appropriate connection between the die and the motherboard. The die and associated interconnection parts are encapsulated with a protective molding. Numerous technologies have been developed to meet these requirements. Some of the research and development strategies focus on new technologies while others focus on improving the existing and mature technologies. Research and development in the existing technologies may take a myriad of different directions.

The die may be affixed with its “active surface” upward, and is then conventionally interconnected by so-called “wire bonding”, in which conductive wires are connected from points on the active surface of the die to the bond pads on the die attach (“upper”) surface of the substrate.

To increase the capacity and performance of the package, a die may be stacked upon a die, to make a stacked die package. A portion of the active surface of the lower die (typically, for example, a peripheral marginal area) is occupied by the wire bonds (the “wire span” area), and no solid piece can be placed directly upon the wire span area. An upper die that is small enough may be placed directly upon another area of the active surface of the lower die (typically, for example, a central region). However, where an upper die is too large to fit within the available region of the lower die, a small sufficiently thick solid spacer (such as a chip of silicon or glass) may be placed directly on the available region of the lower die, and the upper die is then stacked upon the spacer, as shown in FIG. IA. Part of the upper die overhangs, and this part may crack or break (destroying the electronics in the die), as shown in FIG. 1B, when the overhanging part is loaded (as, for example, during the wire bond process, when the capillary contacts the die). Or, where the die is very thin and the overhang is extensive, the overhanging portion may not crack or break, but may flex excessively during the wire bonding procedure, resulting in unacceptable bonds at the die pads.

Alternatively, to increase capacity and performance, a second package may be stacked upon a die (or upon a lower package) to make a stacked package module. Where a spacer is required, or where the second package is spaced asymmetrically over the die or lower package or over the spacer, part of the upper package overhangs. The overhanging part of the upper package may crack or break or, as may be more likely, the upper package may “tilt” when the overhanging part is loaded.

One way to prevent such breakage or tilt is to provide a support for the overhanging part of the upper die or package.

A conventional way to support the overhang is to provide solid insulating spacers upon the lower substrate, peripheral to the lower die. Another conventional way to support the overhang is to provide solid insulating spacers upon the lower die, within the available region of the active side of the die.

Thus, a need still remains for a semiconductor package system providing low cost manufacturing, improved yield, reduced form factor, and improved reliability for the integrated circuit package. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### SUMMARY

This invention is directed to providing support for a die or a package that overhangs a package substrate, and thereby preventing mechanical failure (cracking or breaking) or tilt. The overhanging feature (die or package) is stacked upon one or more of a die or a package or a spacer, and has a portion that overhangs the surface of the substrate on which the stacked features are mounted. According to the invention, discrete bumps made of a polymer (such as an electrically nonconductive epoxy) or a conductive material (such as an electrically conductive material) are interposed between the upper surface of the substrate and the lower surface of the overhanging part of the die or package. The bumps are dimensioned to provide a clearance between the upper surface of the “bottom” substrate and the under surface of the second die or “top” substrate.

The invention is carried out by first determining what height is required for the support; then depositing one or more of the polymer bumps at one or more suitable sites on the substrate; and placing the overhanging die or package onto the feature or features upon which it is stacked. The required height is the same as the accumulated thickness of the feature or features upon which the die or package is stacked (including the sum of thicknesses of, for example, any die, packages, spacers, adhesives layers, etc.). Suitable sites for the bumps are determined according to the extent and position of the features or features upon which the die or package is stacked, the extent of the overhang, and the type and force of any stresses that may be imposed on the die or package during processing.

The bumps have a base where they contact the substrate, which may have a greater and lesser width. The greater width of the bump base is in some embodiments less than ten times the bump height, or in some embodiments less than four times the bump height, or in some embodiments less than two times the bump height; and or in some embodiments the greater width of the bump base is less than the bump height. In preferred bumps the base has a generally round, for example, generally circular, shape; and preferred bumps have a generally round, for example generally circular, shape in sectional views generally parallel to the substrate. Various bump shapes may be suitable. The bump may be narrower at greater distances away from the base, although the base may not necessarily be the widest part of the bump.

The invention can be employed using standard equipment, such as for example a conventional die attach machine and die attach epoxy dispenser. The polymer bumps are applied during placement of the overhanging die or package, and may be made as a part of the step of dispensing the die attach adhesive onto the features upon which the die or package is stacked.

In one aspect the invention features a semiconductor assembly having a semiconductor part, such as a package or a die, mounted in an elevated position in relation to an assembly substrate, in which an overhang of the elevated part (die or package) is supported by one or more polymer bumps.

The stacked feature may be a die, or may be a package including a die mounted onto and electrically interconnected with, an upper package substrate. The stacked feature may be electrically interconnected to the assembly substrate by wire bonds; where the feature is a die, the wire bonds connect pads on the die with bond sites (for example on leads or bond fingers) in the assembly substrate, and where the stacked features is a package, the wire bonds connect bond sites (for example on leads or bond fingers) on the upper package substrate with bond sites (for example on leads or bond fingers) in the assembly substrate.

In some embodiments the stacked feature is stacked over a first die. The first die may be affixed to a die mount region of a die attach side of the assembly substrate, with the active side facing away from the assembly substrate, and electrically interconnected to the substrate by wire bonds connecting pads on the first die with bond sites (for example on leads or bond fingers) in the assembly substrate. Or, the first die may be mounted to a die mount region of a die attach side of the assembly substrate in flip chip fashion, in which the die is mounted with the active side facing the substrate and electrical interconnection is made by conductive balls or bumps attached to pads on the die and to interconnect sites on the die attach region of the substrate.

In another aspect the invention features a method for making a semiconductor assembly, by mounting a first die on an assembly substrate, mounting a die spacer using an adhesive on the first die, depositing discrete epoxy bumps on the assembly substrate, interconnecting the first die onto the assembly substrate, and mounting a second (“stacked”) die or (“top”) package upon the die spacer using an adhesive and upon the bumps. The bumps are dimensioned to provide a clearance between an upper surface of the assembly substrate and a lower surface of the second die or “top” package. Further, the second die or “top” package is interconnected onto the bottom substrate by wire bonds connecting pads on the second die (or bond sites on the “top” package substrate) with bond sites on the assembly substrate. In some embodiments the first die is electrically connected to the assembly substrate by wire bonds connecting pads on the first die with bond sites on the substrate; in other embodiments the first die is electrically connected to the assembly substrate in a flip chip manner.

The invention can be useful in semiconductor packaging and, particularly, in Multi Chip Package (“MCP”) or System in Package (“SiP”) or Multi Package Module (“MPM”) package configurations. It can be used, for example, in computers, in telecommunications, and in consumer and industrial electronics.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1A is a diagrammatic sketch in a sectional view showing a die mounted on a spacer over a lower die on a substrate, showing portions of the second die overhanging the substrate.

FIG. 1B is a diagrammatic sketch in a sectional view showing crack or breakage, or bending or bouncing of an overhanging portion of an upper stacked die as shown in FIG. 1A, as can occur during a wire bonding operation.

FIG. 2A is a diagrammatic sketch in a sectional view showing a stacked die package, in which overhanging portions of the upper die are supported in a conventional fashion by insulating spacers.

FIG. 2B is a diagrammatic sketch in a plan view showing a stage in the construction of the conventional package of FIG. 2A, before the upper die is mounted upon the lower die and insulating spacers.

FIG. 3A is a diagrammatic sketch in a sectional view showing a stacked die package, having four spacers mounted on the lower die, and an upper die mounted on the spacers.

FIG. 3B is a diagrammatic sketch in a plan view showing a stage in the construction of the conventional package of FIG. 3A, before the upper die is mounted upon the four spacers.

FIGS. 4A through 4F are sketches in a sectional view showing stages in the construction of a package according an embodiment to the invention, including bumps to support a stacked die configuration.

FIG. 5 is a diagrammatic sketch in a plan view showing the layout of structures on a conventional package as in FIG. 2B.

FIG. 6 is a diagrammatic sketch in a plan view showing the layout of structures on a package according an embodiment to the invention, as in FIG. 4A through 4F.

FIG. 7 is a diagrammatic sketch in a plan view showing stacked die including overhanging portions of an upper die, supported by polymer bumps according to an embodiment of the invention.

FIG. 8 is a diagrammatic sketch in a sectional view showing an arrangement of a die or package mounted on a spacer over a first die, having an extensive part overhanging the substrate, supported over the substrate by polymer bumps according to an embodiment of the invention.

FIG. 9 is a diagrammatic sketch in a plan view showing the arrangement of a lower die and conventional spacers beneath an upper die or package.

FIG. 10A is a diagrammatic sketch in a plan view showing the arrangement of a lower die, one conventional spacer, and a polymer bump spacer beneath an upper die or package according to an aspect of the invention.

FIG. 10B is a diagrammatic sketch in a plan view showing the arrangement of a lower die and several polymer bump spacers beneath an upper die or package according to an aspect of the invention.

FIG. 11 is a plan view of a semiconductor package in yet another alternative embodiment of the present invention;

FIG. 12 is a cross-sectional view of the semiconductor package along the segment 12--12 of FIG. 11;

FIG. 13 is a cross-sectional view of a semiconductor package in yet another alternative embodiment of the present invention;

FIG. 14 is a cross-sectional view of a semiconductor package in yet another alternative embodiment of the present invention;

FIG. 15 is a cross-sectional view of a semiconductor package in yet another alternative embodiment of the present invention;

FIG. 16 is a cross-sectional view of a semiconductor package in yet another alternative embodiment of the present invention;

FIG. 17 is a cross-sectional view of a semiconductor package in yet another alternative embodiment of the present invention;

FIG. 18 is a top view of a substrate structure in an embodiment of the present invention;

FIG. 19 is a top view of the structure of FIG. 8 in a first device mount phase;

FIG. 20 is a top view of the structure of FIG. 9 in a conductive structure attach phase;

FIG. 21 is a top view of the structure of FIG. 10 in a second device mount phase;

FIG. 22 is a top view of the structure of FIG. 11 in an interconnect attach phase; and

FIG. 23 is a flow chart of a semiconductor package for manufacture of the semiconductor package in an embodiment of the present invention.

### DETAILED DESCRIPTION

In the following description, numerous specific details are given to provide a thorough understanding of the invention. However, it will be apparent that the invention may be practiced without these specific details. In order to avoid obscuring the present invention, some well-known system configurations, and process steps are not disclosed in detail. Likewise, the drawings showing embodiments of the apparatus are semi-diagrammatic and not to scale and, particularly, some of the dimensions are for the clarity of presentation and are shown greatly exaggerated in the figures. In addition, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional integrated circuit surface, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements.

The term “system” means the method and the apparatus of the present invention. The term “processing” as used herein includes deposition of material, patterning, exposure, development, etching, cleaning, molding, and/or removal of the material or as required in forming a described structure.

Referring now to FIG. IA, there is shown a stacked die configuration having a first (“lower”) die 14 mounted on a substrate 12, a spacer 13 mounted on the lower die 14, and a second (“upper”) die 114, larger than the first die 14, mounted upon the spacer 13. The lower die can be affixed to the substrate using a die attach adhesive, the spacer (which may be, for example, a “dummy” die or a chip of glass) can be mounted on the lower die using an adhesive such as a die attach adhesive, and the upper die can be mounted on the spacer using a die attach adhesive (the various adhesives are not shown in the FIGs.). The lower die in this example is electrically interconnected with the substrate by wire bonds (not shown in the FIG.) prior to mounting the larger upper die. Any or all of the die attach adhesives may be, for example, a die attach epoxy, or a die attach film. Because the upper die 114 in the example of FIG. IA is significantly larger than the lower die 14, and because the lower die 14 is to be electrically interconnected to the substrate 12 by wire bonding (not shown in this FIG.), the spacer 13 is required to provide clearance for the wire bond loops over the margins of the lower die. The height 11 between the downward-facing surface of the upper die 114 and the upward-facing surface of the substrate 12 is constituted by the thicknesses of the bottom die and the spacer, and the thicknesses of the various attach adhesives. The upper die 114 is much larger than the spacer 13 that the upper die is mounted upon, and large portions of the upper die project outward from the edges of the spacer, and overhang the edge of the lower die 14 and the substrate 12, as illustrated for example by die overhang 17.

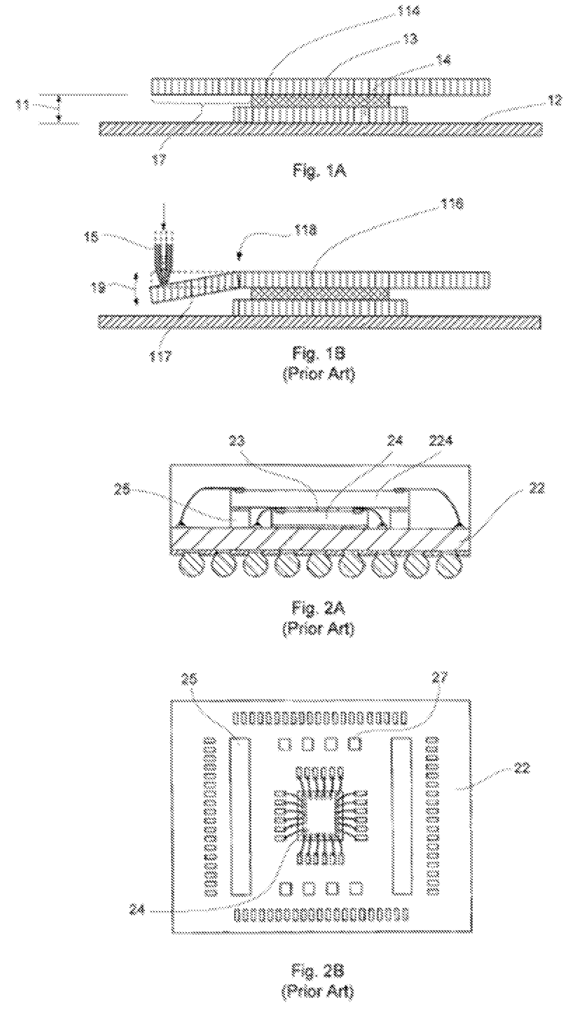

FIG. 1B shows a detrimental effect that may result, for example, by impact of the wire bonding capillary with the die pads on the upper surface of an overhanging part of the second die during a wire bonding operation. Impact of the capillary tip 15 with the die pads on the overhanging part 117 of the die 116 may cause the overhanging part of the die to flex, as shown by the arrow 19 and bounce and/or to crack or break. Flex or bounce can result in poor wire bond interconnection to the die pads; and cracking or breakage of the die, as shown for example at 118, can destroy the circuitry on the die.

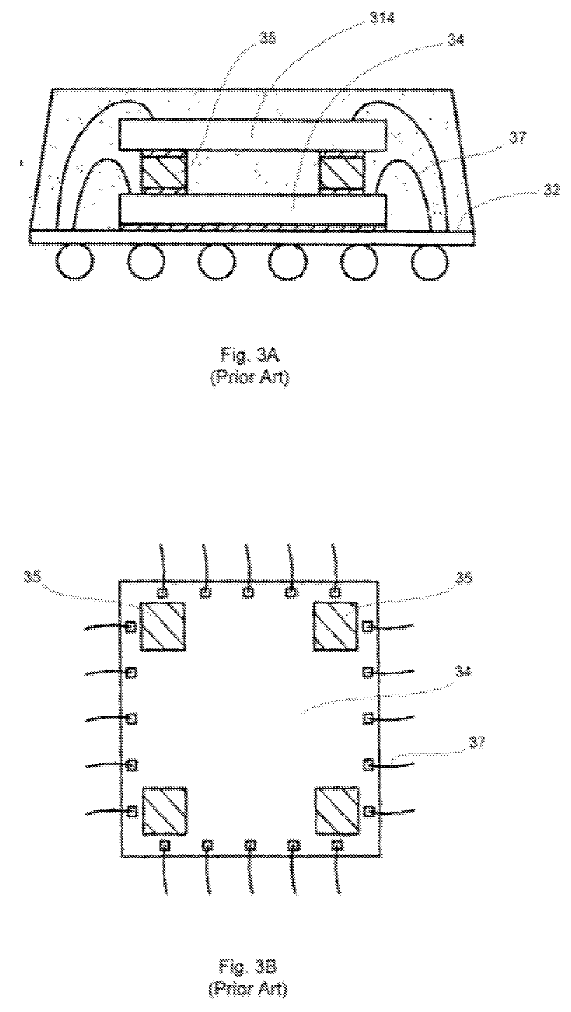

FIGS. 2A and 2B illustrate a conventional approach to supporting an overhanging part of an upper die in a die stack, In this example a first (“lower”) die 24 is affixed, active side upward, using an adhesive onto a die attach surface of a lower substrate 22, and the lower die is electrically connected to the substrate by wire bonds between pads on the die and wire bond sites on an metal layer in the upper layer of the substrate. Electrically insulating block- or bar-shaped spacers 25 are mounted, using an adhesive, upon the lower substrate outside the wire bond sites for interconnection of the lower die and parallel to rows of bond sites for electrical interconnection of the second (“upper”) die 224. An insulating adhesive 23 is provided over the lower die and over the upward-facing surfaces of the spacers, and then the second (“upper”) die 224 is then mounted upon the adhesive 23 on the lower die and the spacers, The adhesive 23 has a thickness that is sufficient when cured that to provide clearance above the lower die 24 for the loop height of the wire bonds, to avoid interference by the upper die 224 with the wire bonds, and the adhesive 23 may appropriately be referred to as a “spacer adhesive”. Then the upper die is electrically interconnected to the substrate by wire bonding to the rows of wire bond pads outside the spacers. FIG. 2B shows stage in the construction of a package as in FIG. 3A, having a lower die 24 and spacers 25, 27 mounted on a substrate 22. The lower die 24 is electrically connected to the substrate 22 by wire bonds connecting pads on the die with bond fingers on the substrate. Spacers 25 and 27 are mounted on the substrate 22 outside (peripheral to) the bond fingers for interconnection of the lower die. Bond fingers for wire bond interconnection of the upper die (not yet placed in this FIG.) are situated outside (peripheral to) the spacers. A significant area of the substrate must be dedicated to the lower die wires, the lower die bond pads in the substrate, and to spacing among these features and between the wire bond sites and the spacers, as is evident in FIG. 2B. Typically, for example, a separation between the lower die bond pads and the space must be at east about 0.5-1.0 mm; and the width of the bond fingers is about 0.4 mm; and the wires themselves may be about 1 mm long.

FIGS. 3A and 3B illustrate another conventional approach to supporting an upper die over a lower die. Here the upper die 314 is about the same size as the lower die 34. In this approach, four smaller spacers 35 are affixed, using an adhesive, to the upward-facing (active) surface of the lower die 34, inboard from the die pads and near the corners of the die, as shown in FIG. 3B; and the upper die is affixed, using an adhesive, to the upward-facing surfaces of the small spacers, as shown in FIG. 3A. This arrangement would do nothing to help support a portion of the upper die that may extend over the substrate, in a case where the upper die is larger than the lower die.

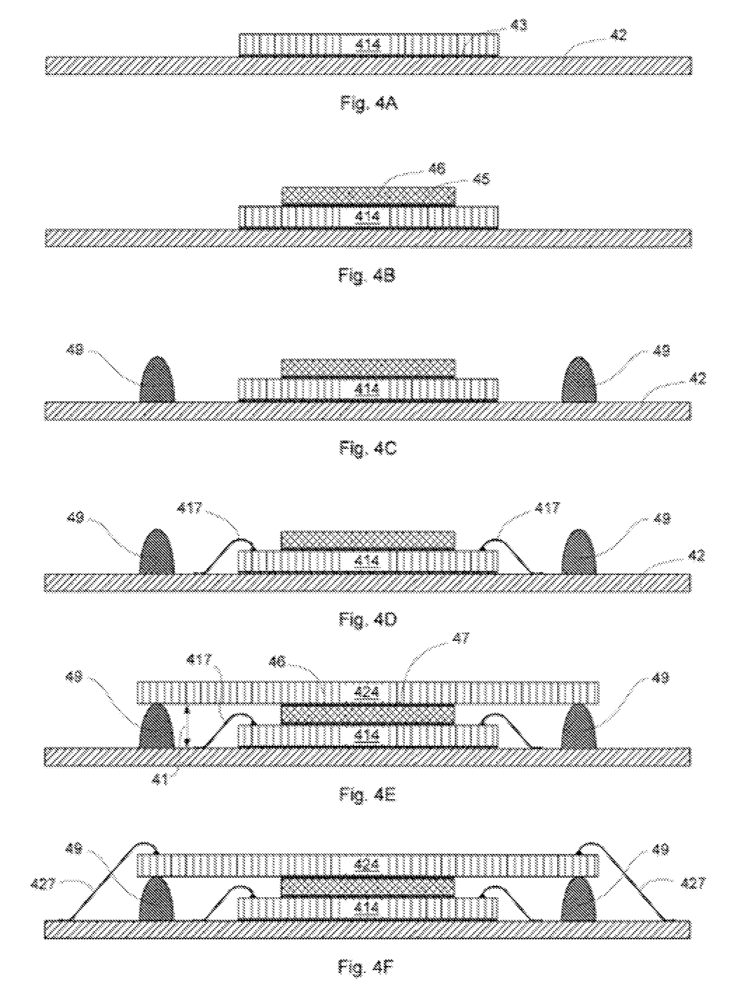

As illustrated in FIGS. 4A through 4F, support for an overhanging upper die or package is provided according to the invention by mounting a first die 414 using an adhesive 43 on a die attach region of the die attach side of the “bottom” substrate 42 (FIG. 4A), mounting a spacer 46 using an adhesive 45 on the first die 414 (FIG. 4B), depositing discrete epoxy bumps 49 on the die attach side of the “bottom” substrate 42 (FIG. 4C), interconnecting the first die 414 onto the bottom substrate 42 by wire bonds 417 connecting pads on the die 414 with bond sites on the substrate (FIG. 4D), and mounting the second die 424 (or “top” package) upon the spacer 46 using an adhesive 47 and upon the bumps 49 (FIG. 4E). The bumps 49 are dimensioned to support overhanging parts of the second die or “top” package at a clearance 41 between the upper surface of the “bottom” substrate and the under surface of the second die or “top” package. The dimension for the clearance 41 is determined as the sum of the thicknesses of the lower die 414 and the spacer 46, plus the thicknesses of the adhesives 43, 45, 47; as will be appreciated, the specifications for the bump height will be affected by the specifications for dimensional change, if any, in the adhesives during the curing process. Then the second die or “top” package is interconnected with the bottom substrate 42 by wire bonds 427 connecting pads on the second die 424 (or bond sites on the “top” package substrate) with bond sites on the substrate, as shown in FIG. 4F. The sequence of steps may at some stages be different; particularly, for example, the steps giving rise to stages 4D and 4C can be reversed. In subsequent steps, the stacked die (or bottom die and top package), the spacer, the bumps, and the wire bond interconnects are encapsulated or molded.

Any of various substrate types may be suitable for the assembly (“bottom”) substrate, providing only that the substrate have sites for electrical interconnection of the various electrical features mounted on and over it according to the invention. The assembly substrate may be, for example, a laminate with 2-6 metal layers, or a build up substrate with 4-8 metal layers, or a flexible polyimide tape with 1-2 metal layers, or a ceramic multilayer substrate. Or, for example, the substrate may be a lead frame.

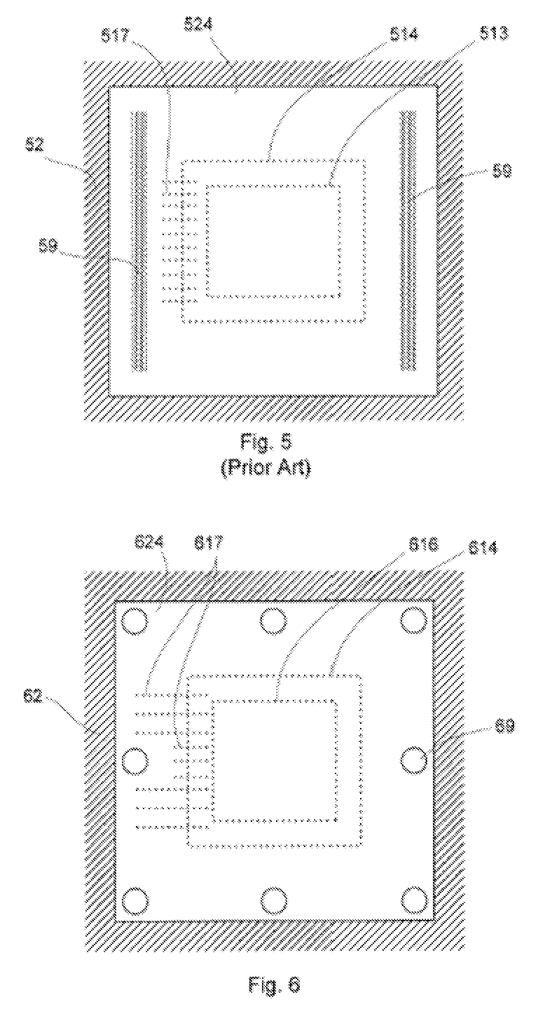

A comparison of a conventional configuration as in FIG. 2B with a configuration according to an embodiment of the invention as in FIG. 4F is made in FIGS. 5 and 6, each showing a plan view of an assembly having a first die mounted upon and electrically connected to a substrate, and a second die mounted over the first die. FIG. 5 shows a stage in construction of a conventional package as in FIG. 2B after the second die has been mounted, but before the second die has been electrically connected to the substrate by wire bonds. The second die 524 and a portion of the underlying substrate 52 are visible in this view. The first die 514, the die spacer adhesive 513, the first die wire bonds, e.g., 517, and the spacers 59 are shown by dotted or broken lines, as they are obscured in this view beneath the second die 524. FIG. 6 shows a stage in construction of a package according to an embodiment of the invention as in FIG. 4F after the second die has been mounted, but before the second die has been electrically connected to the substrate by wire bonds. The second die 624 and a portion of the underlying substrate 62 are visible in this view. The first die 614, the die spacer 616, the first die wire bonds, e.g., 617, and the spacers 69 are shown by dotted or broken lines, as they are obscured in this view beneath the second die 624. In this example, eight discrete epoxy bumps 69 are provided on the “bottom” substrate 62. They are arranged on the “bottom” substrate at the periphery of the second die footprint, to provide maximum support for the overhang. As FIG. 6 shows, the polymer bumps provide more free space on the substrate surface for arrangement of the wires and wire bond pads on the substrate. The choice of positions for the wire bond pads and the polymer support bumps can be adjusted according to particular design consideration for the particular die or package. Thus the package design can be more flexible.

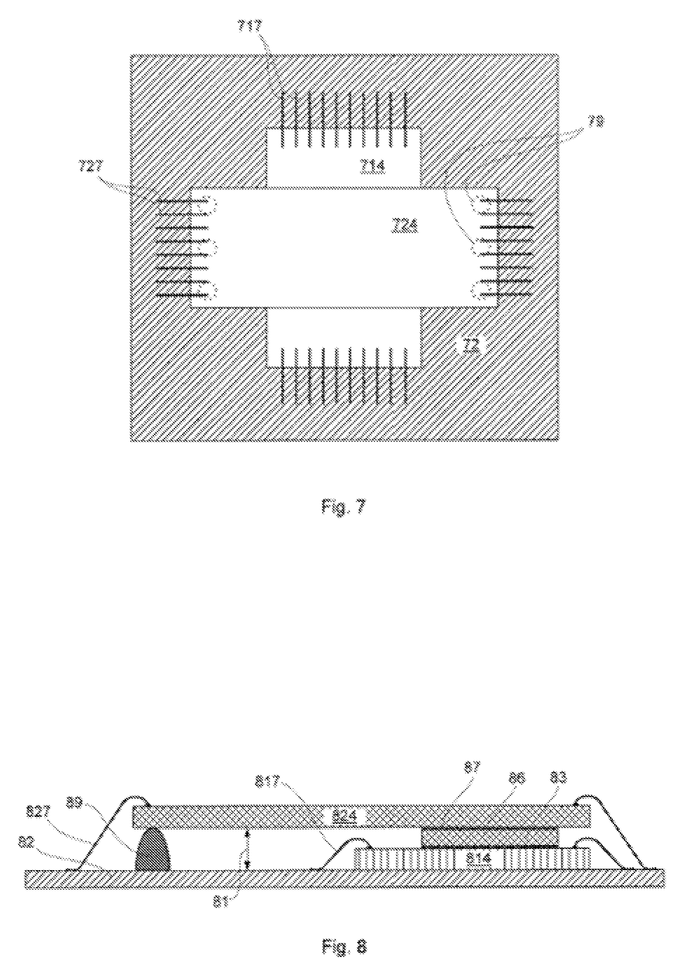

FIG. 7 shows an embodiment of the invention in which rectangular die are stacked, or a rectangular package is stacked over a rectangular die. Here the narrower dimension of the second (“top”) die or package 724 is small enough so that it can be accommodated in an area of the die that is inboard from the wire span areas of the first (“bottom”) die 714. Accordingly they can be arranged so that no spacer is required between the die; epoxy bumps 79 on the “bottom” substrate 72 (obscured by the “top” die or package in this view) support the overhang of the ends of the upper die. As one example of this configuration, the die may be electrically interconnected with the substrate by wire bonds, e.g., 717, 727 connected to die pads arranged along one edge of the die, or (as in the example shown in the FIG.) along two opposite edges of the die. The die may be memory die (of which some types are often rectangular, and significantly longer than wide). The lower die may be a flash memory, and the upper die may be a SRAM, for example; and the SRAM may be sufficiently narrow that no spacer is required between the two die. Nevertheless, because the second die (or package) is significantly longer than the width of the lower die, the significant overhang of the upper die (or package) must be supported over the underlying substrate, particularly where the upper die (or package) may be very thin and flexible, or to avoid tilt.

FIG. 8 shows an embodiment in which an upper die or package 824 is asymmetrically stacked over a spacer 86 on the first (“lower”) die 814. Epoxy bumps 89 on the “bottom” substrate 82 support the extensively overhanging (cantilevered) end of the upper die or package, preventing breakage (of a “top” die) or tilt (of a “top” die or package). The first (“bottom”) die 814 is interconnected with the substrate 82 by wire bonds 817 connecting pads on the die with bond pads on the substrate; and the second (“top”) die or package is interconnected by wire bonds 827 connecting pads on the die (or interconnect sites on the upper package substrate) with bond pads on the substrate 82. The spacer 86 is affixed to the bottom die 814 using an adhesive 83, and the second die or package 824 is affixed to the spacer 86 using an adhesive 87. The bumps 89 are dimensioned to provide a clearance 81 between the upper surface of the “bottom” substrate and the under surface of the second die or “top” package. The dimension for the clearance 81 is determined as the sum of the thicknesses of the lower die 814 and the spacer 86, plus the thicknesses of the adhesives 83, 87; as will be appreciated, the specifications for the bump height will be affected by the specifications for dimensional change, if any, in the adhesives during the curing process.

The material for the epoxy bumps may be applied using a syringe, for example, or other adhesive dispense tool; or, the bumps may be applied by printing and, in this approach, the bumps may preferably be applied prior to mounting the first die (and die spacer, where required). The polymer constituting the bumps may be a “filled” epoxy, for example, or an epoxy whose rheology and viscosity characteristics permit it to hold an attitude as a bump (without collapsing) until it can be cured to hardness. Typically the epoxy of the bumps is cured following mounting of the upper die or package, in a curing step that may additionally cure one or all of the attachment adhesives. An epoxy may be used that can be cured in stages; such an epoxy may be partially cured following bump formation but prior to mounting the second die or package, and then fully cured following mounting of the upper die or package, in a curing step that may additionally cure one or all of the attachment adhesives. A stage-curable epoxy may be preferred, as this may provide improved stability during assembly steps subsequent to forming the bumps.

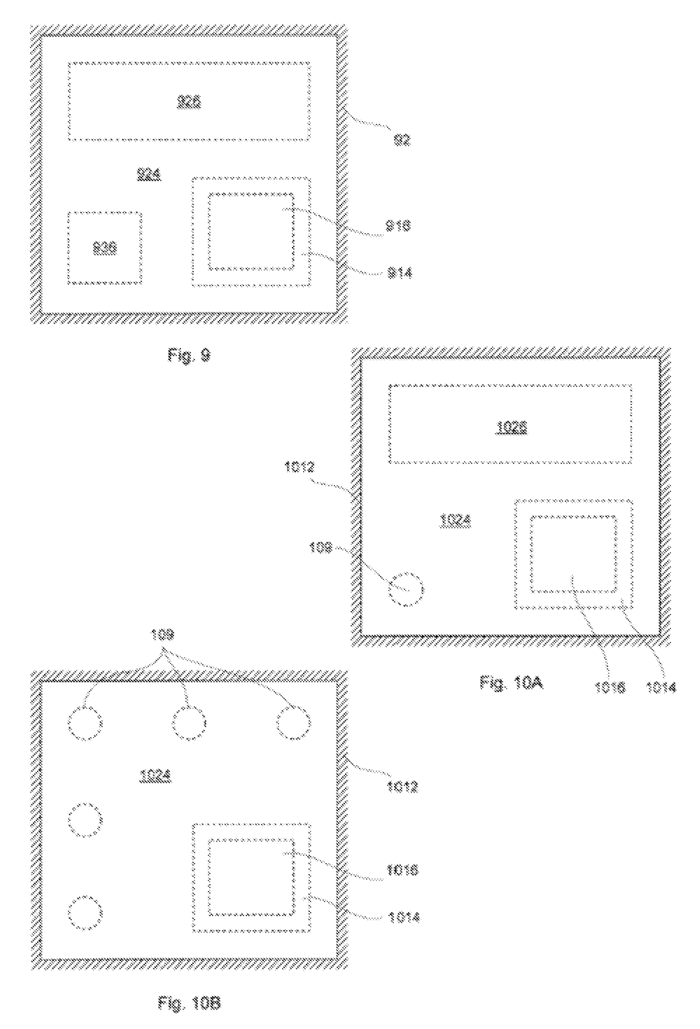

Placement of the polymer support bumps is illustrated in particular examples in FIGS. 9 and 10A and 10B. In these examples, an upper die (or package) is to be stacked over a lower die; the lower die is provided with a die spacer so that the upper die or package does not interfere with the wire bonds connecting pads on the lower die with bond sites on the substrate. In the view shown in each of these FIGs., the second (“upper”) die or package obscures all the features beneath it except a portion of the substrate that extends beyond the edge of the second die or package. Because the upper die or package is much larger than the lower die or package, in a conventional arrangement (FIG. 9), first 926 and second 936 spacers are required to support the extensive portions of the upper die 924 that extend beyond the lower die 914 spacer 916 and overhang the substrate 92. The clearance between the downward-facing side of the top die or package and the upward-facing side of the bottom substrate is determined by the thicknesses of the bottom die and the die spacer, plus the thicknesses of the adhesives by which the bottom die is attached to the substrate, the die spacer is attached to the bottom die, and the top die or package is attached to the die spacer; and the first and second spacers 926 and 936 are dimensioned, together with adhesives associated with them, to support the second die or package and to maintain the clearance of the second die or package over the substrate. In the configuration of FIG. 10A, a spacer 1026 is provided, but there is no second spacer; instead a polymer bump 109 according to the invention is employed to support the corner of the upper die or package 1024 that would conventionally (as in FIG. 9) have been supported by a second spacer; the clearance between the downward-facing side of the top package or substrate and the upward-facing side of the bottom substrate 1012 is determined by the thickness of the bottom die 1014 and the die spacer 1016 mounted on it, plus the thicknesses of the adhesives by which the bottom die is attached to the substrate, the die spacer is attached to the bottom die, and the top die or package is attached to the die spacer. In FIG. 10B, both the first spacer and the second spacer are absent, and five epoxy bumps 109 have been placed according to the invention so as to provide support in place of the spacers.

Other embodiments are within the invention.

In any of the configurations described above, the overhanging feature may be either a die or a package. Particularly, for example, in a multi-package module the upper feature may be a package having lands exposed on the upward-facing side of the upper package substrate, for wire bond interconnection to the substrate; the upper package may be inverted. Examples of multipackage modules having upper packages interconnected with the module by wire bonds are disclosed, for example, in Kamezos U.S. application Ser. No. 101632,549, filed Aug. 2, 2003; and in Karnezos U.S. application Ser. No. 101681,572, filed Oct. 8, 2003. Examples of multipackage modules having a stacked inverted package overhanging a module substrate are shown, for example, in Karnezos et al. U.S. application Ser. No. 101022,375, filed Dec. 23, 2004. All patents and patent applications referenced herein are hereby incorporated herein by reference.

In any of the configurations described above, the lower die may be mounted onto the substrate by flip chip interconnect. In such embodiments the active side of the die faces the substrate, and interconnection is made by bumps or balls between die pads and interconnect sites on the substrate within the footprint of the die. No spacer over a flip chip lower die is necessary, inasmuch as there are no wire bonds between the die and the substrate, and the second feature may be mounted, using an adhesive, directly onto the first die. In such embodiments the clearance between the substrate and the stacked feature (that is, the height of the epoxy bumps supporting the overhanging part of the stacked feature) is determined by the thickness of the first die, together with the thickness of the interconnection (collapsed interconnect ball or bumps height) and the thickness of the adhesive by which the second feature is affixed to the first die.

Details of die structures or of package structures are omitted from the drawings for simplicity of presentation. Such structures would be well understood to the skilled artisan in light of the drawings and the description herein

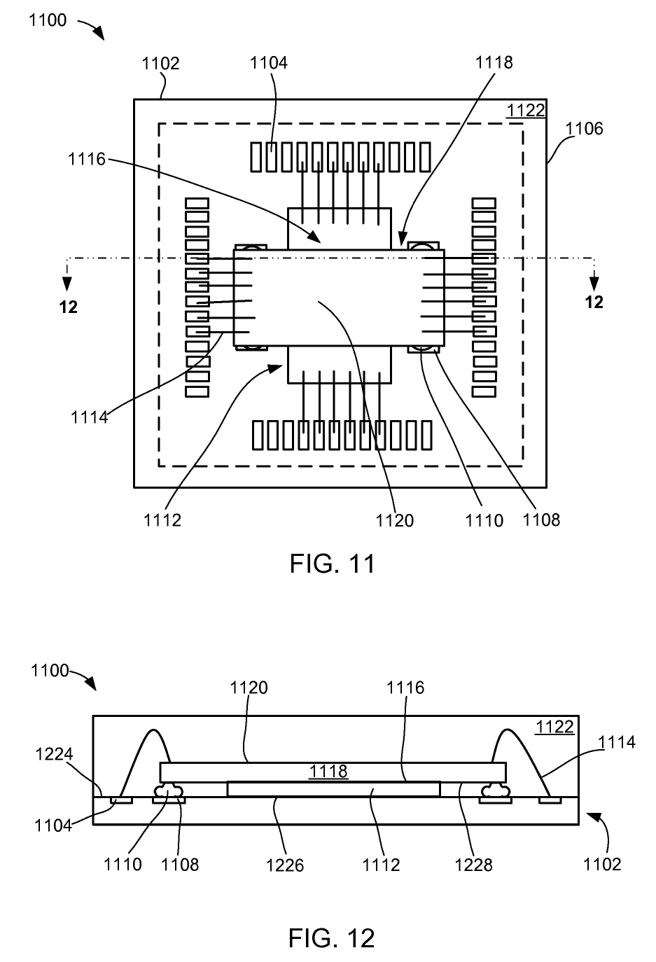

FIG. 11 is a plan view of a semiconductor package system 100 in yet another alternative embodiment of the present invention. The plan view depicts a substrate 1102, such as a carrier, having contact pads 1104, such as lead fingers or terminal pads. The contact pads 1104 are along edges 1106 of the substrate 1102. The substrate 1102 also has support pads 1108, such as pads of conductive material. The support pads 1108 are within the periphery outlined by the contact pads 1104.

The contact pads 1104 are part of the conductive traces (not shown) of the substrate 1102 for electrical and thermal conduction. The support pads 1108 may or may not be part of the conductive structures (not shown) of the substrate 1102. The support pads 1108 may be part of the conductive structures and may be tied to ground of the next system level (not shown), such as a printed circuit board or another device.

The support pads 1108 may be connected to form structures serving multiple functions, such as a ground connection, a thermal dissipation path, or an electromagnetic interference (EMI) shield. Conductive bumps 1110, such as stud bumps, are on the support pads 1108. The conductive bumps 1110 with the support pads 1108 may form structures serving multiple functions, such as a ground connection, a thermal dissipation path, or an electromagnetic interference (EMI) shield.

A first device 1112, such as an integrated circuit die or a packaged device, is over the substrate 1102. Interconnects 1114, such as bond wires, connect between the contact pads 1104 and a first active side 1116 of the first device 1112. A second device 1118, such as an integrated circuit die or a packaged device, is over the first device 1112 and the conductive bumps 1110. The interconnects 1114 connect between the contact pads and a second active side 1120 of the second device 1118. For illustrative purposes, the first device 1112 and the second device 1118 are shown both connected with the interconnects 1114, although it is understood that the first device 1112 and the second device 1118 may be connected to the substrate 1102 with different interconnect types, such as solder bumps or bond wires.

An encapsulation 1122, such as an epoxy mold compound, covers the contact pads 1104, the support pads 1108, the conductive bumps 1110, the first device 1112, the second device 1118, the interconnects 1114, and a portion of the substrate 1102.

FIG. 12 is a cross-sectional view of the semiconductor package system 1100 along the segment 12--12 of FIG. 11. The substrate 1102 has the contact pads 1104 and the support pads 1108 along a first substrate side 1224. For illustrative purposes, the substrate 1102 is shown as uniform aside from the contact pads 1104 and the support pads 1108, although it is understood that the substrate 1102 may not be uniform and may have conductive structures, such as conductive traces, different layers of conductive traces, and electrical vias.

The first device 1112 has a first nonactive side 1226 facing and over the first substrate side 1224. The second device 1118 is over the first device 1112. A second nonactive side 1228 of the second device 1118 is facing the first active side 1116. Portions of the second device 1118 overhang the first device 1112.

The conductive bumps 1110 are on the support pads 1108 and provide support to the overhanging portions of the second device 1118. The substrate 1102 functions as a support platform for the conductive bumps 1110. The conductive bumps 1110 provide structural support to the second device 1118 from the second nonactive side 1228 and mitigate damage to the second device 1118 as the semiconductor package system 1100 undergoes packaging. The conductive bumps 1110 mitigate damage to the second device 1118 from the vertical force exerted in the attachment process of the interconnects 1114 to the second active side 1120.

It has been discovered that the conductive bumps 1110 provides vertical structural support. The conductive bumps 1110 may also serve other functions. The conductive bumps 1110 may be tied to ground and provide grounding to the body of the second device 1118. The conductive bumps 1110, tied to ground, may provide ground connection options to the second device 1118. The conductive bumps 1110, tied to ground, may also function as an electromagnetic interference (EMI) shield. Alternatively, the conductive bumps 1110 may be tied to a voltage reference or source other than ground to provide a bias connection option, a voltage source connection option, or both. The conductive bumps 1110 may further function as a heat dissipation path. The conductive bumps 1110 also form mold locks for the semiconductor package system 1100.

The interconnects 1114 connect the second active side 1120 and the contact pads 1104. The encapsulation 1122 covers the contact pads 1104, the support pads 1108, the conductive bumps 1110, the first device 1112, the second device 1118, the interconnects 1114, and a portion of the first substrate side 1224.

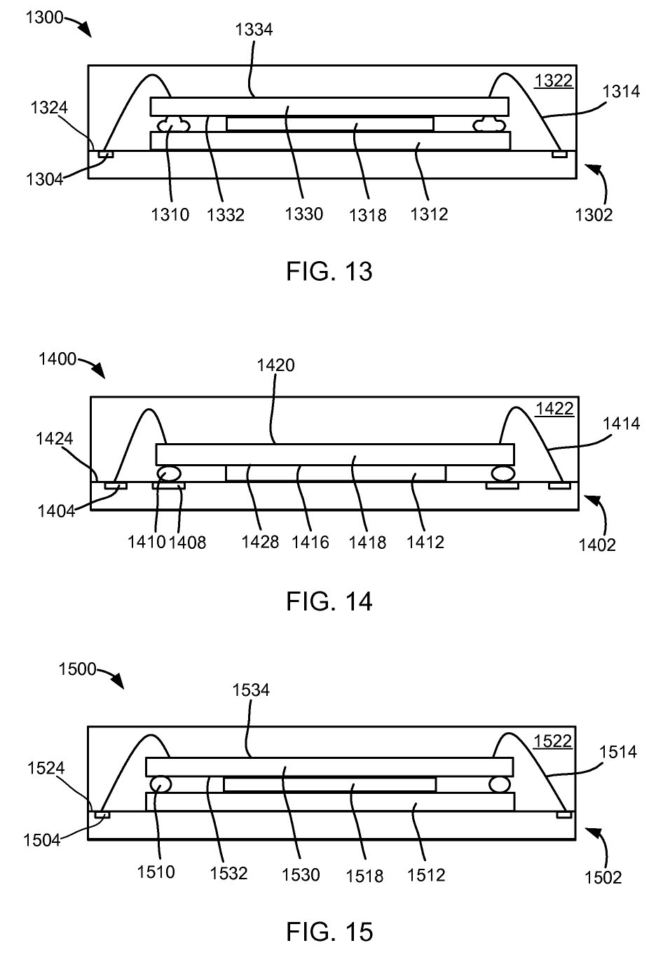

FIG. 13 is a cross-sectional view of a semiconductor package system 1300 in yet another alternative embodiment of the present invention. A substrate 1302 has contact pads 1304, such as lead fingers or terminal pads, along a first substrate side 1324. For illustrative purposes, the substrate 1302 is shown as uniform aside from the contact pads 1304, although it is understood that the substrate 1302 may not be uniform and may have conductive structures (not shown), such as conductive traces, different layers of conductive traces, and electrical vias.

A first device 1312, such as an integrated circuit die or a packaged device, is over the first substrate side 1324. A second device 1318, such as an integrated circuit die or a packaged device, is over the first device 1312. A third device 1330, such as an integrated circuit die or a packaged device, is over the second device 1318. Portions of the third device 1330 overhang the second device 1318.

Conductive bumps 1310, such as stud bumps, are between the first device 1312 and the overhanging portions of the third device 1330. The first device 1312 functions as a support platform for the conductive bumps 1310. The conductive bumps 1310 provide structural support to the third device 1330 from a third nonactive side 1332 of the third device 1330 and mitigates damage to the third device 1330 as the semiconductor package system 1300 undergoes packaging. The conductive bumps 1310 mitigate damage to the third device 1330 from the vertical force exerted in the attachment process of interconnects 1314, such as bond wires, to a third active side 1334 of the third device 1330. The conductive bumps 1310 may be formed at the wafer level of the first device 1312 or the third device 1330.

The conductive bumps 1310 provide vertical structural support. The conductive bumps 1310 may also serve other functions. The conductive bumps 1310 may be tied to ground and provide grounding the body of the third device 1330. The conductive bumps 1310, tied to ground, may provide ground connection options to the third device 1330. The conductive bumps 1310, tied to ground, may also function as an electromagnetic interference (EMI) shield. Alternatively, the conductive bumps 1310 may be tied to a voltage reference or source other than ground to provide a bias connection option, a voltage source connection option, or both. The conductive bumps 1310 may further function as a heat dissipation path. The conductive bumps 1310 may also serve as probe points for test and prevent adverse wear of the bond pads (not shown) of the first device 1312.

The interconnects 1314 connect the third active side 1334 and the contact pads 1304. An encapsulation 1322, such as an epoxy mold compound (EMC), covers the contact pads 1304, the conductive bumps 1310, the first device 1312, the second device 1318, the third device 1330, the interconnects 1314, and a portion of the first substrate side 1324. The conductive bumps 1310 also form mold locks for the semiconductor package system 1300.

FIG. 14 is a cross-sectional view of a semiconductor package system 1400 in yet another alternative embodiment of the present invention. This cross-sectional view may be that of the semiconductor package system 100 of FIG. 1. A substrate 1402 has contact pads 1404, such as lead fingers or terminal pads, and support pads 1408 along a first substrate side 1424. For illustrative purposes, the substrate 1402 is shown as uniform aside from the contact pads 1404 and the support pads 1408, although it is understood that the substrate 1402 may not be uniform and may have conductive structures, such as conductive traces, different layers of conductive traces, and electrical vias.

A first device 1412 is over the first substrate side 1424. A second device 1418 is over the first device 1412. A second nonactive side 1428 of the second device 1418 is facing a first active side 1416 of the first device 1412. Portions of the second device 1418 overhang the first device 1412.

Conductive bumps 1410, such as solder bumps, are on the support pads 1408 and provide support to the overhanging portions of the second device 1418. The substrate 1402 functions as a support platform for the conductive bumps 1410. The conductive bumps 1410 provide structural support to the second device 1418 from the second nonactive side 1428 and mitigate damage to the second device 1418 as the semiconductor package system 1400 undergoes packaging. The conductive bumps 1410 mitigate damage to the second device 1418 from the vertical force exerted in the attachment process of interconnects 1414, such as bond wires, to a second active side 1420.

The conductive bumps 1410 provide vertical structural support. The conductive bumps 1410 may also serve other functions. The conductive bumps 1410 may be tied to ground and provide grounding the body of the second device 1418. The conductive bumps 1410, tied to ground, may provide ground connection options to the second device 1418. The conductive bumps 1410, tied to ground, may also function as an electromagnetic interference (EMI) shield. Alternatively, the conductive bumps 1410 may be tied to a voltage reference or source other than ground to provide a bias connection option, a voltage source connection option, or both. The conductive bumps 1410 may further function as a heat dissipation path. The conductive bumps 1410 also form mold locks for the semiconductor package system 1400.

The interconnects 1414 connect the second active side 1420 and the contact pads 1404. An encapsulation 1422, such as an epoxy mold compound (EMC), covers the contact pads 1404, the support pads 1408, the conductive bumps 1410, the first device 1412, the second device 1418, the interconnects 1414, and a portion of the first substrate side 1424.

FIG. 15 is a cross-sectional view of a semiconductor package system 1500 in yet another alternative embodiment of the present invention. A substrate 1502 has contact pads 1504, such as lead fingers or terminal pads, along a first substrate side 1524. For illustrative purposes, the substrate 1502 is shown as uniform aside from the contact pads 1504, although it is understood that the substrate 1502 may not be uniform and may have conductive structures (not shown), such as conductive traces, different layers of conductive traces, and electrical vias.

A first device 1512, such as an integrated circuit die or a packaged device, is over the first substrate side 1524. A second device 1518, such as an integrated circuit die or a packaged device, is over the first device 1512. A third device 1530, such as an integrated circuit die or a packaged device, is over the second device 1518. Portions of the third device 1530 overhang the second device 1518.

Conductive bumps 1510, such as solder bumps, are between the first device 1512 and the overhanging portions of the third device 1530. The first device 1512 functions as a support platform for the conductive bumps 1510. The conductive bumps 1510 provide structural support to the third device 1530 from a third nonactive side 1532 of the third device 1530 and mitigates damage to the third device 1530 as the semiconductor package system 1500 undergoes packaging. The conductive bumps 1510 mitigate damage to the third device 1530 from the vertical force exerted in the attachment process of interconnects 1514, such as bond wires, to a third active side 1534 of the third device 1530. The conductive bumps 1510 may be formed at the wafer level of the first device 1512 or the third device 1530.

The conductive bumps 1510 provide vertical structural support. The conductive bumps 1510 may also serve other functions. The conductive bumps 1510 may be tied to ground and provide grounding the body of the third device 1530. The conductive bumps 1510, tied to ground, may provide ground connection options to the third device 1530. The conductive bumps 1510, tied to ground, may also function as an electromagnetic interference (EMI) shield. Alternatively, the conductive bumps 1510 may be tied to a voltage reference or source other than ground to provide a bias connection option, a voltage source connection option, or both. The conductive bumps 1510 may further function as a heat dissipation path. The conductive bumps 1510 may also serve as probe points for test and prevent adverse wear of the bond pads (not shown) of the first device 1512.

The interconnects 1514 connect the third active side 1534 and the contact pads 1504. An encapsulation 1522, such as an epoxy mold compound (EMC), covers the contact pads 1504, the conductive bumps 1510, the first device 1512, the second device 1518, the third device 1530, the interconnects 1514, and a portion of the first substrate side 1524. The conductive bumps 1510 also form mold locks for the semiconductor package system 1500.

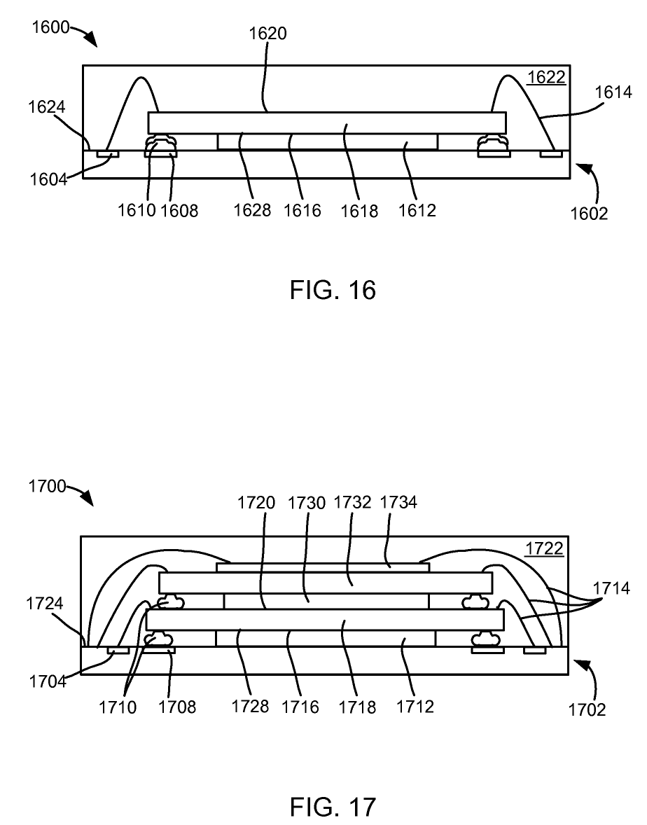

FIG. 16 is a cross-sectional view of a semiconductor package system 1600 in another alternative embodiment of the present invention. This cross-sectional view may be that of the semiconductor package system 1100 of FIG. 11. A substrate 1602 has contact pads 1604, such as lead fingers or terminal pads, and support pads 1608 along a first substrate side 1624. For illustrative purposes, the substrate 1602 is shown as uniform aside from the contact pads 1604 and the support pads 1608, although it is understood that the substrate 1602 may not be uniform and may have conductive structures, such as conductive traces, different layers of conductive traces, and electrical vias.

A first device 1612 is over the first substrate side 1624. A second device 1618 is over the first device 1612. A second nonactive side 1628 of the second device 1618 is facing a first active side 1616 of the first device 1612. Portions of the second device 1618 overhang the first device 1612.

Conductive bumps 1610, such as stud bump stack, are on the support pads 1608 and provide support to the overhanging portions of the second device 1618. The substrate 1602 functions as a support platform for the conductive bumps 1610. The conductive bumps 1610 provide structural support to the second device 1618 from the second nonactive side 1628 and mitigate damage to the second device 1618 as the semiconductor package system 1600 undergoes packaging. The conductive bumps 1610 mitigate damage to the second device 1618 from the vertical force exerted in the attachment process of interconnects 1614, such as bond wires, to a second active side 1620.

The conductive bumps 1610 provide vertical structural support. The conductive bumps 1610 may also serve other functions. The conductive bumps 1610 may be tied to ground and provide grounding the body of the second device 1618. The conductive bumps 1610, tied to ground, may provide ground connection options to the second device 1618. The conductive bumps 1610, tied to ground, may also function as an electromagnetic interference (EMI) shield. Alternatively, the conductive bumps 1610 may be tied to a voltage reference or source other than ground to provide a bias connection option, a voltage source connection option, or both. The conductive bumps 1610 may further function as a heat dissipation path. The conductive bumps 1610 also form mold locks for the semiconductor package system 1600.

The interconnects 1614 connect the second active side 1620 and the contact pads 1604. An encapsulation 1622, such as an epoxy mold compound (EMC), covers the contact pads 1604, the support pads 1608, the conductive bumps 1610, the first device 1612, the second device 1618, the interconnects 1614, and a portion of the first substrate side 1624.

FIG. 17 is a cross-sectional view of a semiconductor package system 1700 in another alternative embodiment of the present invention. A substrate 1702 has contact pads 1704, such as lead fingers or terminal pads, and support pads 1708 along a first substrate side 1724. For illustrative purposes, the substrate 1702 is shown as uniform aside from the contact pads 1704 and the support pads 1708, although it is understood that the substrate 1702 may not be uniform and may have conductive structures, such as conductive traces, different layers of conductive traces, and electrical vias.

A first device 1712, such as an integrated circuit die or a packaged device, is over the first substrate side 1724. A second device 1718, such as an integrated circuit die or a packaged device, is over the first device 1712. A second nonactive side 1728 of the second device 1718 is facing a first active side 1716 of the first device 1712. Portions of the second device 1718 overhang the first device 1712.

Conductive bumps 1710, such as stud bumps, are on the support pads 1708 and provide support to the overhanging portions of the second device 1718. The substrate 1702 functions as a support platform for the conductive bumps 1710. The conductive bumps 1710 provide structural support to the second device 1718 from the second nonactive side 1728 and mitigate damage to the second device 1718 as the semiconductor package system 1700 undergoes packaging. The conductive bumps 1710 mitigate damage to the second device 1718 from the vertical force exerted in the attachment process of interconnects 1714, such as bond wires, to a second active side 1720.

The conductive bumps 1710 provide vertical structural support. The conductive bumps 1710 may also serve other functions. The conductive bumps 1710 may be tied to ground and provide grounding the body of the second device 1718. The conductive bumps 1710, tied to ground, may provide ground connection options to the second device 1718. The conductive bumps 1710, tied to ground, may also function as an electromagnetic interference (EMI) shield. Alternatively, the conductive bumps 1710 may be tied to a voltage reference or source other than ground to provide a bias connection option, a voltage source connection option, or both. The conductive bumps 1710 may further function as a heat dissipation path. The conductive bumps 1710 also form mold locks for the semiconductor package system 1700.

The interconnects 1714 connect the second active side 1720 and the contact pads 1704. A third device 1730, such as an integrated circuit die or a packaged device, is over the second device 1718 and below a fourth device 1732, such as an integrated circuit die or a packaged device. The third device 1730 is between the conductive bumps 1710 over the second device 1718. The conductive bumps 1710 over the second device 1718 provide structural support to overhanging portions of the fourth device 1732. The interconnects 1714 also connect the fourth device 1732 and the substrate 1702.

A fifth device 1734, such as an integrated circuit die or a packaged device, is over the fourth device 1732 and does not impede the connections of the interconnects 1714 attached to the fourth device 1732. The interconnects 1714 also connect the fifth device 1734 and the substrate 1702.

An encapsulation 1722, such as an epoxy mold compound (EMC), covers the contact pads 1704, the support pads 1708, the conductive bumps 1710, the first device 1712, the second device 1718, the third device 1730, the fourth device 1732, the fifth device 1734 the interconnects 1714, and a portion of the first substrate side 1724.

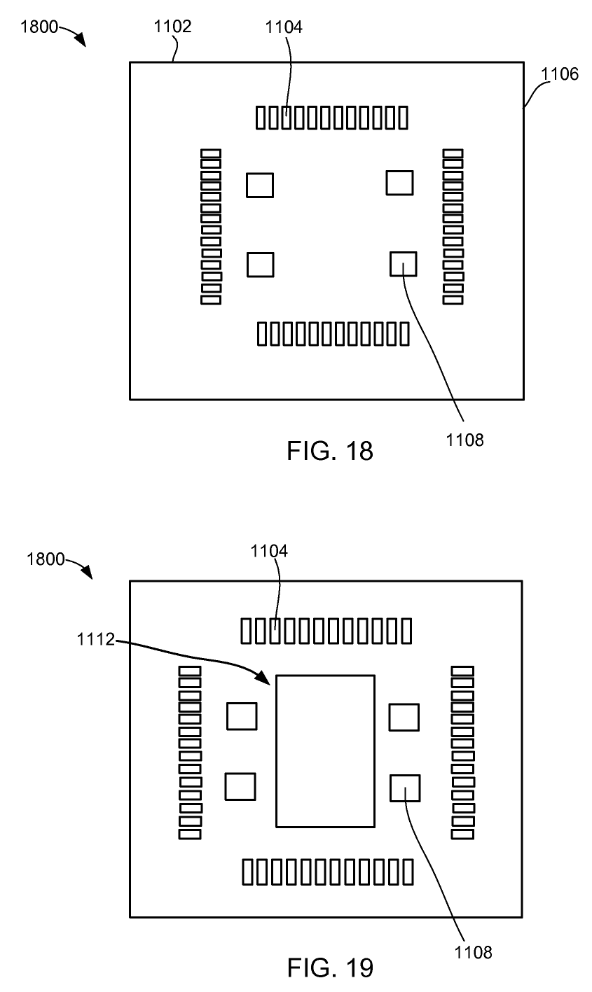

FIG. 18 is a top view of a substrate structure 800 in an embodiment of the present invention. The substrate structure 1800 may represent the substrate 1102 of FIG. 11 or an array of the substrate 102. The top view depicts the substrate structure 1800, such as a substrate, having the contact pads 1104, such as lead fingers or terminal pads. The contact pads 1104 are along the edges 1106 of the substrate structure 1800. The substrate structure 1800 also has the support pads 1108, such as pads of conductive material. The support pads 1108 are within the periphery outlined by the contact pads 1104.

The contact pads 1104 are part of the conductive traces (not shown) of the substrate structure 1800 for electrical and thermal conduction. The support pads 1108 may or may not be part of the conductive structures (not shown) of the substrate structure 1800. The support pads 1108 may be part of the conductive structures and may be tied to ground of the next system level (not shown), such as a printed circuit board or another device.

FIG. 19 is a top view of the structure of FIG. 18 in a first device mount phase. The first device 1112 is attached on the substrate structure 1800 between the contact pads 1104 and the support pads 1108. The first device 1112 may be attached on the substrate structure 1800 by any number of processes, such as die-attach with an adhesive (not shown).

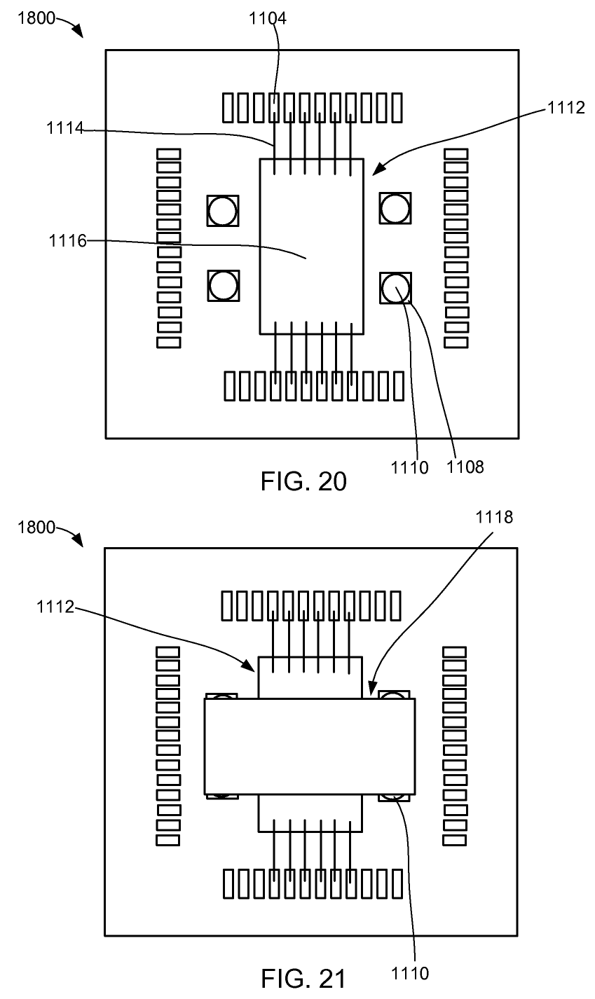

FIG. 20 is a top view of the structure of FIG. 19 in a conductive structure attach phase. The interconnects 1114 are attached between the first active side 1116 of the first device 1112 and predetermined selection of the contact pads 1104 of the substrate structure 800. The conductive bumps 1110 are formed on the support pads 1108. The conductive bumps 1110 may be formed using the same process as the attachment process of the interconnects 1114, such as wire bonding process.

FIG. 21 is a top view of the structure of FIG. 20 in a second device mount phase. The second device 1118 is mounted over the first device 1112 and the substrate structure 1800. Portions of the second device 1118 overhang the first device 1112 and supported by the conductive bumps 1110.

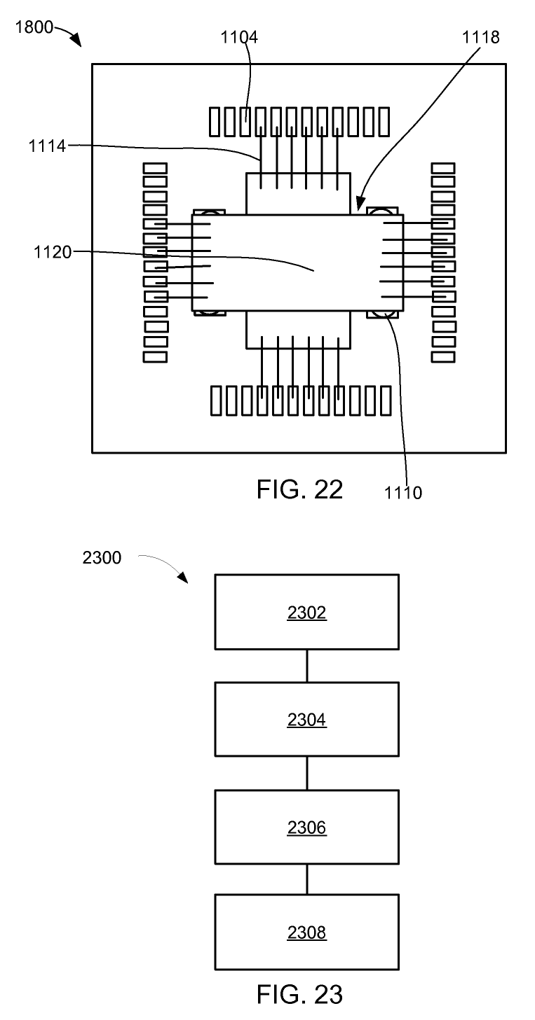

FIG. 22 is a top view of the structure of FIG. 21 in an interconnect attach phase. The interconnects 1114 are attached between the second active side 1120 of the second device 1118 and predetermined selection of the contact pads 1104 of the substrate structure 800. The attachment process exerts a vertical force on the overhanging portions of the second device 1118. The conductive bumps 1110 provide structural support to the second device 1118 and allowing the second device 1118 to withstand the attachment process. This structure undergoes a molding process. This structure may have a plurality of the structures, such as in an array, that undergoes singulation to form the semiconductor package system 1100.

FIG. 23 is a flow chart of a semiconductor package system 1300 for manufacture of the semiconductor package system 100 in an embodiment of the present invention. The system 2300 includes forming a support platform in a block 2302; mounting a first device over the support platform in a block 2304; forming a bump on the support platform in a block 2306; and mounting a second device on the first device and the bump in a block 2308.

It has been discovered that the present invention thus has numerous aspects.

It has been discovered that the present invention provides conductive bump structures that increases yields of stacked integrated circuit structures, simplifies the manufacturing process, improves electrical performance, improves thermal performance, and improves the overall structural rigidity of the semiconductor package system.

An aspect of the present invention provides forming conductive bumps, such as stud bumps, with the same or similar interconnect attachment process, such as wire bonding. This simplifies the manufacturing process and reduces cost. The conductive bumps may also be formed at the wafer level prior to singulation forming integrated circuit dice.

Another aspect of the present invention provides forming conductive bumps, such as solder bumps, with the same or similar interconnect attachment process, such as solder on pad (SOP). This simplifies the manufacturing process and reduces cost. The conductive bumps may also be formed at the wafer level prior to singulation forming integrated circuit dice.

Yet another aspect of the present invention is that the conductive bumps provide vertical structural support. The conductive bumps provide structural support to the overhanging device and mitigate damage to the overhanging device as the semiconductor package system undergoes packaging. The conductive bumps mitigate damage to the overhanging device from the vertical force exerted in the attachment process of interconnects, such as bond wires, to the overhanging device.

Yet another aspect of the present invention is that the conductive bumps may be tied to ground and provide grounding the body of the overhanging integrated circuit die. The conductive bumps, tied to ground, may provide ground connection options to the overhanging device.

Yet another aspect of the present invention is that the conductive bumps, tied to ground, may also function as an electromagnetic interference (EMI) shield.

Yet another aspect of the present invention is that the conductive bumps may be tied to a voltage reference or source other than ground to provide a bias connection option, a voltage source connection option, or both.

Yet another aspect of the present invention is that the conductive bumps may further function as a heat dissipation path.

Yet another aspect of the present invention is that the conductive bumps may also serve as probe points for test and prevent adverse wear of the bond pads (not shown) of the integrated circuit die or the substrate.

Yet another aspect of the present invention is that the conductive bumps may also serve as mold locks for the semiconductor package system.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the semiconductor package system method of the present invention furnishes important and heretofore unknown and unavailable solutions, capabilities, and functional aspects for improving reliability in systems. The resulting processes and configurations are straightforward, cost-effective, uncomplicated, highly versatile, and effective, can be implemented by adapting known technologies, and are thus readily suited for efficiently and economically manufacturing integrated circuit package devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A semiconductor package system comprising:
forming a support platform;
mounting a first device over the support platform;
forming a bump on the support platform; and
mounting a second device on the first device and the bump.

2. The system as claimed in claim 1 wherein forming the bump includes forming a stud bump, a solder bump, or a stack with one or both with a conductive material.

3. The system as claimed in claim 1 wherein forming the support platform includes forming a substrate.

4. The system as claimed in claim 1 further comprising mounting a third device on the second device.

5. The system as claimed in claim 1 wherein forming the support platform includes:
forming a third device having the bump thereon; and
further comprising:
forming a substrate; and
mounting the third device over the substrate.

6. A semiconductor package system comprising:
forming a support platform;
mounting a first integrated circuit die over the support platform;
forming a bump on the support platform; and
mounting a second integrated circuit die on the first integrated circuit die and the bump.

7. The system as claimed in claim 6 wherein forming the support platform includes:
forming a substrate; and
further comprising:
connecting the first integrated circuit die and the substrate;
connecting the second integrated circuit die and the substrate; and
molding the first integrated circuit die, the second integrated circuit die, the bump, and the substrate.

8. The system as claimed in claim 6 wherein forming the support platform includes:
forming a third integrated circuit die having the bump thereon; and
further comprising:
forming a substrate;
connecting the third integrated circuit die and the substrate;
connecting the first integrated circuit die and the substrate;
connecting the second integrated circuit die and the substrate; and
molding the first integrated circuit die, the second integrated circuit die, the third integrated circuit die, the bump, and the substrate.

9. The system as claimed in claim 6 wherein:
forming the support platform includes:
forming a substrate having a support pad; and
forming the bump on the support platform further includes:
forming the bump on the support pad.

10. The system as claimed in claim 6 wherein:
forming the support platform includes:
forming a substrate having a support pad; and
forming the bump on the support platform further includes:
forming the bump on the support pad; and
further comprising:
connecting a voltage reference to the bump.

11. A semiconductor package system comprising:
a support platform;
a first device over the support platform;
a bump on the support platform; and
a second device on the first device and the bump.

12. The system as claimed in claim 11 wherein the bump is a stud bump, a solder bump, or a stack with one or both.

13. The system as claimed in claim 11 wherein the support platform is a substrate.

14. The system as claimed in claim 11 further comprising a third device on the second device.

15. The system as claimed in claim 11 wherein the support platform is a third device having the bump thereon and further comprising:
a substrate having the third device thereover.

16. The system as claimed in claim 11 wherein:
the support platform has a conductive structure;
the first device is a first integrated circuit die over the support platform;
the bump is next to the first device on the support platform; and
the second device is a second integrated circuit die on the first device and the bump.

17. The system as claimed in claim 16 wherein the support platform is a substrate and further comprising:
an interconnect between the first integrated circuit die and the substrate as well as between the second integrated circuit die and the substrate; and
an encapsulation to cover the first integrated circuit die, the second integrated circuit die, the bump, and the substrate.

18. The system as claimed in claim 16 wherein the support platform is a third integrated circuit die and further comprising:
a substrate with the third integrated circuit die thereon;
an interconnect between the first integrated circuit die and the substrate as well as between the second integrated circuit die and the substrate; and
an encapsulation to cover the first integrated circuit die, the second integrated circuit die, the third integrated circuit die, the bump, and the substrate.

19. The system as claimed in claim 16 wherein:
the support platform is a substrate; and
the bump on the support platform is on a support pad of the substrate.

20. The system as claimed in claim 16 wherein:
the support platform is a substrate; and
the bump on the support platform is on a support pad of the substrate for a connection to a voltage reference.
